(19) United States
(12) Patent Application Publication
(10) Pub. No.: US 2006/0038711 A1
(43) Pub. Date: Feb. 23, 2006

(54) Apparatus for channel balancing of multi-channel analog-to-digital converter and method thereof

(75) Inventors: Yu Pin Chou, Tongxiao Town (TW); An Shih Lee, Taoyuan city (TW); Tsu Chun Wang, Chupei City (TW); Jui Yuan Tsai, Tainan city (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: REALTEK SEMICONDUCTOR CORP., Hsien (TW)

(21) Appl. No.: 11/196,273

(22) Filed: Aug. 4, 2005

(30) Foreign Application Priority Data
Aug. 10, 2004 (TW) 093123975

(51) Int. Cl. H03M 1/12

(52) U.S. Cl. 341/155

(57) ABSTRACT

An apparatus for channel balancing of a multi-channel analog-to-digital converter of a digital image display comprises a red, a green and a blue analog-to-digital converter for respectively receiving a red, a green and a blue analog signal of an image signal wherein the analog-to-digital converters respectively sample the red, green and blue analog signals through a sampling clock signal and output a corresponding digital signal. A phase difference processing unit is used for estimating the phase differences among the digital signals and outputting corresponding time delay signals according to the phase differences. A clock delay compensation unit is used for receiving the time delay signals and respectively compensating the time delays of the sampling clock signals of the analog-to-digital converters according to the time delay signals, thereby decreasing the phase differences among the digital signals. The present invention also provides a method for channel balancing of a multi-channel analog-to-digital converter of a digital image display.

### CROSS REFERENCE TO RELATED APPLICATION

This application claims the priority benefit of Taiwan Patent Application Serial Number 093123975, filed Aug. 10, 2004, the full disclosure of which is incorporated herein by reference.

### BACKGROUND OF THE INVENTION

1. Field of the Invention

This invention generally relates to a multi-channel analog-to-digital converter, and more particularly to an apparatus and method for channel balancing of a multi-channel analog-to-digital converter.

2. Description of the Related Art

In a digital image display system, an analog image signal is typically separated into red (R), green (G) and blue (B) analog signals. The red, green and blue analog signals are converted into corresponding digital signals respectively through three analog-to-digital converters and output to a display screen.

In such a system, there usually exists a channel mismatch or channel unbalance problem since the analog-to-digital conversion processes of the red, green and blue analog signals are accomplished respectively through three different channels, i.e. R/G/B channels. Generally, the channel mismatch or channel unbalance may lead to incorrect color or contrast or poor image caused by phase differences among the R/G/B channels. Accordingly, it is significant to achieve inter channel balance among the R/G/B channels: In the prior art, the channel match or balance can generally be achieved by appropriately designing the layout of a printed circuit board. Also, it can be achieved by adjusting the DC offsets and the gains of the three channels. However, although appropriately designing the layout of the printed circuit board for achieving the channel balance can reach an improvement, the impact caused by a slight channel mismatch may be not acceptable for some applications such as high-frequency analog-to-digital converters. In addition, the layout mismatch inside an IC chip and the mismatch inside the signal source all may cause the signal unbalance or mismatch among the R/G/B channels and thus cause an image color shift problem. Further, an inappropriate sampling phase may produce an unreliable signal and thus lead to a poor display image.

Accordingly, the present invention provides an apparatus and method for channel balancing of a multi-channel analog-to-digital converter, which can be used for compensating the signal unbalance or mismatch among the R/G/B channels so as to overcome the image color shift problem.

### SUMMARY OF THE INVENTION

It is an object of the present invention to provide an apparatus and method for channel balancing of a multi-channel analog-to-digital converter, which can be used for compensating the unbalance or mismatch among the R/G/B channels so as to overcome the image color shift problem.

According to an embodiment of the present invention, an apparatus for channel balancing of a multi-channel analog-to-digital converter of a digital image display is disclosed. The apparatus comprises a red, a green and a blue analog-to-digital converter, a phase difference processing unit and a clock delay compensation unit. The analog-to-digital converters are respectively used for sampling a red, a green and a blue analog signal of an image signal through a sampling clock signal and outputting a corresponding digital signal; the phase difference processing unit is used for estimating the phase differences among the digital signals and outputting corresponding time delay signals according to the phase differences; and the clock delay compensation unit is used for respectively compensating the time delays of the sampling clock signals of the analog-to-digital converters according to the time delay signals, thereby decreasing the phase differences among the digital signals and thus compensating the unbalance or mismatch among the R/G/B channels.

An exemplary embodiment of the present invention provides a method for channel balancing of a digital image display, which comprising following steps: sampling a plurality of analog signals respectively by a plurality of analog-to-digital converters according to a plurality of sampling clock signals and outputting a plurality of corresponding digital signals respectively by the analog-to-digital converters; estimating phase differences among the digital signals; and adjusting the sampling clock signals according to the phase differences, thereby decreasing the phase differences among the digital signals.

### BRIEF DESCRIPTION OF THE DRAWINGS

Other objects, advantages, and novel features of the present invention will become more apparent from the following detailed description when taken in conjunction with the accompanying drawings.

FIG. 1 is a block view of an apparatus for channel balancing of a multi-channel analog-to-digital converter of a digital image display according to one embodiment of the present invention.

FIG. 2 is a graph showing the relation between the SOD value and the phase of the red, green and blue digital signals.

FIG. 3 is a graph showing the relation between the SOD value and the phase of the red digital signal.

FIG. 4 is a detailed circuit of a clock delay compensation unit according to one embodiment of the present invention.

### DETAILED DESCRIPTION OF THE PREFERRED EMBODIMENT

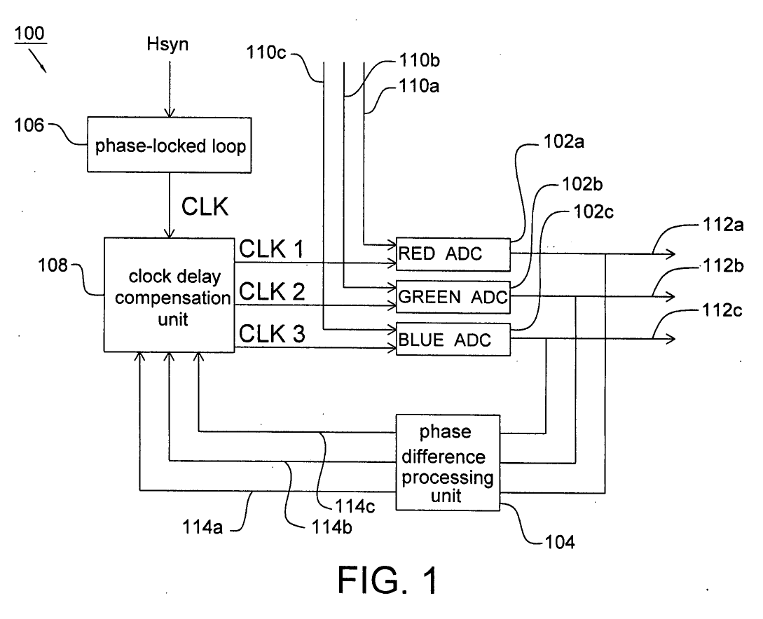

Now referring to FIG. 1, it shows a block view of an apparatus 100 for channel balancing of a multi-channel analog-to-digital converter of a digital image display according to one embodiment of the present invention. The apparatus 100 comprises a red (R) analog-to-digital converter 102a, a green (R) analog-to-digital converter 102b, a blue (B) analog-to-digital converter 102c, a phase difference processing unit 104, a phase-locked loop 106 and a clock delay compensation unit 108. The phase-locked loop 106 is used for receiving a horizontal synchronization signal (Hsync) and outputting a clock signal CLK to the clock delay compensation unit 108. The red, green and blue analog-to-digital converters 102a, 102b and 102c are respectively used for receiving a red, a green and a blue analog signal 110a, 110b and 110c of an image signal and sampling the red, green and blue analog signals 110a, 110b and 110c by the sampling rates of three clock signals CLK1, CLK2 and CLK3. In this embodiment, the three clock signals CLK1, CLK2 and CLK3 are identical to the output clock signal CLK of the phase-locked loop 106 while R/G/B channels are balanced. On the contrary, the apparatus 100 operates the way as following while the R/G/B channels are unbalanced or mismatched.

The analog-to-digital converters 102a, 102b and 102c will respectively output a red, a green and a blue digital signal 112a, 112b and 112c to a display panel (not shown) after respectively sampling the red, green and blue analog signals 110a, 110b and 110c. Besides, the output red, green and blue digital signals 112a, 112b and 112c will be respectively transmitted to the phase difference processing unit 104.

The phase difference processing unit 104 is mainly used for estimating the phase differences among the red, green and blue digital signals 112a, 112b and 112c thereby obtaining the corresponding delay times among the same. After obtaining the delay times, the phase difference processing unit 104 will respectively output time delay signals 114a, 114b and 114c, which are corresponding to the delay times, to the clock delay compensation unit 108. The clock delay compensation unit 108 is used for respectively compensating the clock signal CLK with three delay times according to the time delay signals 114a, 114b and 114c, thereby producing and outputting the clock signals CLK1, CLK2 and CLK3 to the red, green and blue analog-to-digital converters 102a, 102b and 102c such that the phase differences among the red, green and blue digital signals 112a, 112b and 112c are decreased.

In this embodiment, the phase difference processing unit 104 can respectively process the red, green and blue digital signals 112a, 112b and 112c with sum of difference (SOD) operation. For example, if the value of the red digital signal 112a is R[n] where 1<=n<=M, the SOD value of the red digital signal 112a can be calculated by following steps:

1. SOD[0]=0; R[0]=0;

2. For each n, if the absolute value of (R[n]−R[n−1]) is greater than or equal to a threshold value, then SOD[n]=SOD[n−1]+ABS(R[n]−R[n−1]) wherein ABS(R[n]−R[n−1]) represents the absolute value of (R[n]−R[n−1]); and

3. The SOD value is SOD[M].

It should be understood that the present invention is not limited by the SOD operation, and other operations capable of calculating the phase relation among the digital signals can also be applied to this embodiment.

In the embodiment of the present invention, the phase difference processing unit 104 can calculate the SOD values of the red, green and blue digital signals 112a, 112b and 112c and then determine the relative relation between the SOD value and the phase of each digital signal 112a, 112b and 112c.

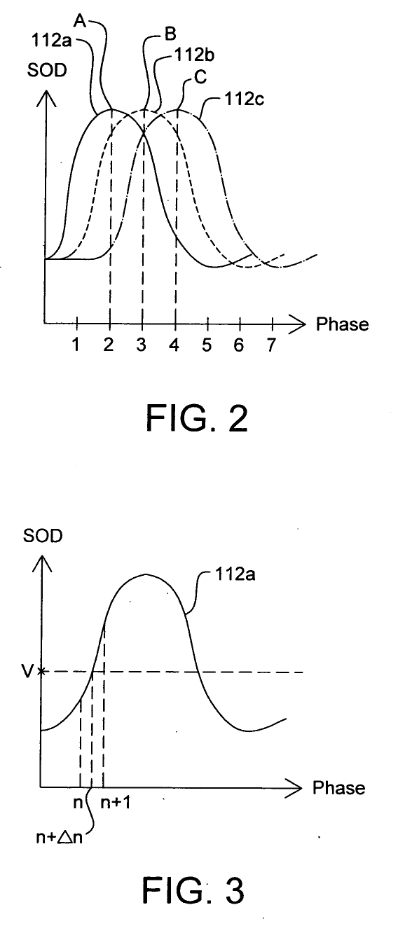

Referring to FIG. 2, it shows the relation between the SOD value and the phase of the red, green and blue digital signals 112a, 112b and 112c. It could be understood from FIG. 2 that there exist phase differences among the red, green and blue digital signals 112a, 112b and 112c; therefore, these digital signals are mismatched.

One feature of the present invention is that the phase difference processing unit 104 can calculate the phase differences among the red, green and blue digital signals 112a, 112b and 112c, and then the clock delay compensation unit 108 can respectively compensate the clock signal CLK with three delay times according to the phase differences thereby producing and outputting the clock signals CLK1, CLK2 and CLK3 to the red, green and blue analog-to-digital converters 102a, 102b and 102c. In this manner, the phase differences among the red, green and blue digital signals 112a, 112b and 112c can be decreased by the respective compensation for the clock signal CLK.

As shown in FIG. 2, the phase differences among the digital signals 112a, 112b and 112c can be obtained by comparing three reference phases respectively corresponding to three relative points on the digital signals 112a, 112b and 112c. In one embodiment of the present invention, the three reference phases are respectively corresponding to the top point, i.e. the largest SOD value of each digital signal 112a, 112b and 112c. In FIG. 2, the three reference phases corresponding to the largest SOD values A, B, and C of the digital signals 112a, 112b and 112c are respectively 2, 3 and 4. Therefore, it could be understood that the red digital signal 112a leads the green digital signal 112b by one phase unit, and the green digital signal 112b further leads the blue digital signal 112c by one phase unit.

In this embodiment, the sampling delay of the clock signal CLK includes eight settings, t+0×Tph, t+1×Tph, t+2×Tph, t+3×Tph, t+4×Tph, t+5×Tph, t+6×Tph and t+7×Tph, wherein Tph is equal to the delay time of one phase unit and a predetermined sampling delay of the clock signal CLK is t+3×Tph. Accordingly, the sampling delays of the input clock signals CLK1, CLK2 and CLK3 of the analog-to-digital converters 102a, 102b and 102c will be compensated as t+4×Tph, t+3×Tph and t+2×Tph when the reference phases of the digital signals 112a, 112b and 112c are respectively 2, 3 and 4, such that the phase differences among the digital signals 112a, 112b and 112c output from the red, green and blue analog-to-digital converters 102a, 102b and 102c can be compensated so as to achieve phase match condition. The compensating manner described above is achieved by respectively delaying the clock signal CLK for 4, 3 and 2 phase unit time so as to produce the clock signals CLK1, CLK2 and CLK3; therefore, the reference phases corresponding to the largest SOD values A, B and C of the digital signals 112a, 112b and 112c are respectively all adjusted from 4, 3 and 2 to 3 since the predetermined sampling delay of the clock signal CLK is t+3×Tph, thereby achieving phase match condition.

In another embodiment of the present invention, the reference phase of each digital signal 112a, 112b and 112c can also be calculated by interpolation method. As shown in FIG. 3, it is a graph showing the relation between the SOD value and the phase of the red digital signal 112a. Firstly, an appropriate SOD value V is predetermined on the rising edge of the digital signal 112a. If the reference phase n+Δn corresponding to the SOD value V is positioned between n and n+1, then the reference phase n+Δn can be obtained by interpolation method. For example, if the rising edge of the digital signal 112a is linear, then An can be obtained by linear interpolation method wherein Δn=ABS(V−SOD[n])/ABS(SOD[n+1]−SOD[n]), where ABS(V−SOD[n]) and ABS(SOD[n+1]−SOD[n]) respectively represent the absolute value of (V−SOD[n]) and (SOD[n+1]−SOD[n]).

Similarly, the reference phases of the digital signals 112b and 112c can also be obtained according to the above method. Also, as shown in FIG. 3, the SOD values can be normalized such that the obtained reference phases are more precise. After obtaining the reference phase of each digital signal 112a, 112b and 112c, the delay times for being compensated to the clock signal CLK can be determined according to the phase differences so as to achieve phase match of the digital signals 112a, 112b and 112c.

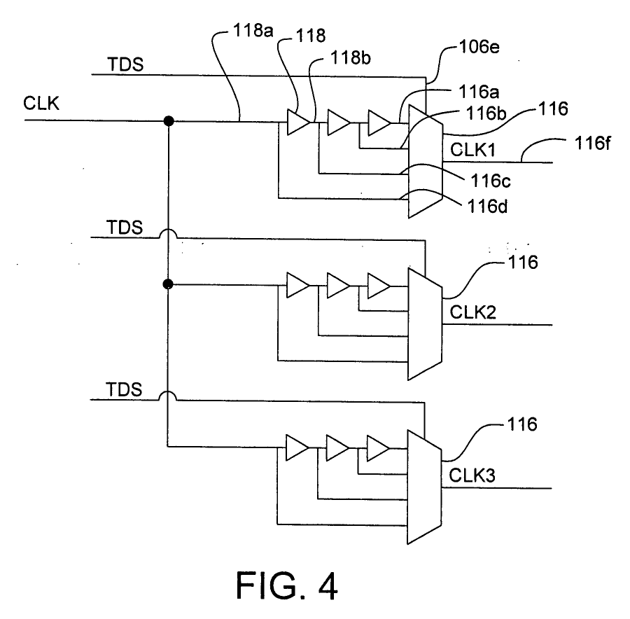

As shown in FIG. 4, it is a detailed circuit of the clock delay compensation unit 108 according to one embodiment of the present invention. The clock delay compensation unit 108 includes three multiplexers 116. Each multiplexer 116 has four inputs 116a, 116b, 116c and 116d, two select lines (only shown in one line) 116e and an output 116f. Each input 116a of the multiplexer 116 is connected to three series-coupled buffer units 118. Each buffer unit 118 has an input 118a and an output 118b and provides an output delay time. The four inputs 116a, 116b, 116c and 116d of each multiplexer 116 are respectively and electrically connected to the outputs 118b of the three buffer units 118 and the input 118a of the leftmost buffer unit 118. The input 118a of the leftmost buffer unit 118 is used for receiving the clock signal CLK generated by the phase-locked loop 106. The select lines (only shown in one line) 116e of the three multiplexers 116 are used for respectively receiving the time delay signals (TDS) 114a, 114b and 114c such that an appropriate input signal at the input 116a, 116b, 116c or 116d can be selected and outputted to the output 116f according to the time delay signals 114a, 114b and 114c.

In the embodiment of the present invention, it is assumed that each buffer unit 118 provides 1 ns of output delay time, and thus the input 116a, 116b, 116c and 116d of the multiplexer 116 will respectively receive the clock CLK with delay times 3 ns, 2 ns, 1 ns and 0 ns. In addition, it is assumed that the delay times (i.e. phase differences) estimated by the phase difference processing unit 104 are respectively 3 ns, 2 ns and 1 ns, then the time delay signals (TDS) 114a, 114b and 114c outputted by the phase difference processing unit 104 will select the input signals of the inputs 116a, 116b and 116c respectively at the corresponding multiplexers 116 to be outputted, such that the outputs 116f of the multiplexers 116 can respectively output clock signals CLK1, CLK2 and CLK3 to the red, green and blue analog-to-digital converters 102a, 102b and 102c.

In this embodiment, the clock signals CLK1, CLK2 and CLK3 respectively have delay times 3 ns, 2 ns and 1 ns while compared to the clock signal CLK, such that the phases of the red, green and blue digital signal 112a, 112b and 112c respectively outputted by the red, green and blue analog-to-digital converters 102a, 102b and 102c can be compensated. In this manner, the phases of the red, green and blue digital signal 112a, 112b and 112c can be matched thereby effectively resolving the image color shift problem.

The present invention also provides a method for channel balancing of a multi-channel analog-to-digital converter of a digital image display, which comprises following steps:

(a) providing a plurality of analog-to-digital converters, e.g. the red, green and blue analog-to-digital converters 102a, 102b and 102c as shown in FIG. 1, wherein the analog-to-digital converters respectively receive a plurality of analog component signals of an image signal, e.g. the red, green and blue analog signals 110a, 110b and 110c, respectively sample the plurality of analog component signals by the sampling rates of sampling clock signals, and respectively output a plurality of corresponding digital signals, e.g. the output red, green and blue digital signals 112a, 112b and 112c;

(b) estimating the phase differences among the digital signals, for example: the phase differences among the red, green and blue digital signal 112a, 112b and 112c being estimated by the phase difference processing unit 104 (as shown in FIG. 1), and thereby obtaining the corresponding delay times among the digital signals; and

(c) compensating the time delays of the sampling clock signals according to the phase differences and thereby decreasing the phase differences among the digital signals, wherein the time delays can be represented by absolute times, one-nth (1/n) of phase or one-nth (1/n) of cycle. For example, after obtaining the delay times, the phase difference processing unit 104 will respectively output time delay signals 114a, 114b and 114c, which are corresponding to the delay times, to the clock delay compensation unit 108 as shown in FIG. 1. The clock delay compensation unit 108 is used for respectively compensating the clock signal CLK with three delay times according to the time delay signals 114a, 114b and 114c, thereby producing and outputting the clock signals CLK1, CLK2 and CLK3 to the red, green and blue analog-to-digital converters 102a, 102b and 102c. After the respective compensation for the clock signal CLK with the three delay times, the clock signals CLK1, CLK2 and CLK3 can be adjusted such that the phase differences among the red, green and blue digital signals 112a, 112b and 112c are decreased.

In this embodiment, the step (b) further comprises the step of calculating the sum of difference (SOD) value of each digital signal and determining the relation between the SOD value and the phase of each digital signal, thereby estimating the phase differences among the digital signals by comparing the relation between the SOD value and the phase of each digital. Further, at least one of the steps (a), (b) and (c) can be repeatedly performed such that the phase differences among the digital signals can be closer and more precise.

In the above embodiments, the R/G/B component signals are taken as an example but not used to limit the present invention. If an image signal comprises Y/Cb/Cr component signals, then the present invention can be utilized after the Y/Cb/Cr component signals are converted into RIG/B component signals through a color converter.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is

1. An apparatus for inter channel balancing of multi-channel analog-to-digital converter comprising:
a plurality of analog-to-digital converters for respectively sampling a plurality of analog signals through sampling clock signals and outputting a plurality of corresponding digital signals;
a phase difference processing unit for estimating the phase differences among the digital signals and outputting a plurality of time delay signals according to the phase differences; and
a clock delay compensation unit for adjusting the sampling clock signals of the analog-to-digital converters according to the time delay signals, thereby decreasing the phase differences among the digital signals.

2. The apparatus as claimed in claim 1, wherein the phase difference processing unit determines a relation between the SOD (sum of difference) value and the phase of each digital signal, thereby estimating the phase differences among the digital signals by comparing the relation between the SOD value and the phase of each digital.

3. The apparatus as claimed in claim 1, wherein the clock delay compensation unit comprises a plurality of series-coupled buffer units and each buffer unit provides an output delay time for adjusting the sampling clock signals of the analog-to-digital converters.

4. The apparatus as claimed in claim 3, wherein the clock delay compensation unit further comprises one or more multiplexers for adjusting the sampling clock signals of the analog-to-digital converters according to a selected delay time provided by the plurality of series-coupled buffer units, wherein the selected delay time is determined by the time delay signals.

5. The apparatus as claimed in claim 1, which is disposed in a digital image display.

6. The apparatus as claimed in claim 5, wherein the plurality of analog-to-digital converters comprise three analog-to-digital converters and the analog signals are red, green and blue component signals of an image signal.

7. The apparatus as claimed in claim 1, wherein at least one of the phases of the digital signals is obtained according to an interpolation method.

8. A method for inter channel balancing of multi-channel analog-to-digital converter comprising following steps:
sampling a plurality of analog signals respectively by a plurality of analog-to-digital converters according to a plurality of sampling clock signals and outputting a plurality of corresponding digital signals respectively by the analog-to-digital converters;
estimating phase differences among the digital signals; and
adjusting the sampling clock signals according to the phase differences, thereby decreasing the phase differences among the digital signals.

9. The method as claimed in claim 8, wherein the step of estimating phase differences further comprises following steps:
determining a relation between the SOD (sum of difference) value and the phase of each digital signal; and
estimating the phase differences among the digital signals according to the relation between the SOD value and the phase of each digital.

10. The method as claimed in claim 8, wherein the analog signals are red, green and blue component signals of an image signal.

11. The method as claimed in claim 8, wherein at least one of the steps can be repeatedly performed.

12. The method as claimed in claim 8, further comprising a step of converting a plurality of original signals into the plurality of analog signals.

13. The method as claimed in claim 12, wherein the plurality of original signals are respectively Y, Cb and Cr component signals of an image signal.

14. The method as claimed in claim 8, wherein at least one of the phases of the digital signals is obtained according to an interpolation method.
